(19) United States
(12) Patent Application Publication
(10) Pub. No.: US 2006/0192246 A1
(43) Pub. Date: Aug. 31, 2006

(54) Semiconductor memory device that uses metal nitride as trap site and method of manufacturing the same

(76) Inventors: Sang-Hun Jeon, Seoul (KR); Chung-Woo Kim, Gyeonggi-do (KR); Hyun-Sang Hwang, Gwangju-si (KR); Sang-Moo Choi, Gwangju-si (KR)

Correspondence Address: MARGER JOHNSON & MCCOLLOM, P.C., 210 SW MORRISON STREET, SUITE 400, PORTLAND, OR, 97204, US

(21) Appl. No.: 11/365,114

(22) Filed: Feb. 28, 2006

(30) Foreign Application Priority Data
Feb. 28, 2005 (KR) 10-2005-0016936

(51) Int. Cl. H01L 29/788; H01L 29/76

(52) U.S. Cl. 257/315; 257/382

(57) ABSTRACT

In one embodiment, a memory device includes a gate structure comprising a metal nitride material in a charge storing layer on a semiconductor substrate. The gate structure is disposed between a first dopant region and a second dopant region formed on the semiconductor substrate. The metal nitride material is structured to function as a trap site for trapping a charge.

### CROSS-REFERENCE TO RELATED PATENT APPLICATION

This application claims the benefit of Korean Patent Application No. 10-2005-0016936, filed on Feb. 28, 2005, in the Korean Intellectual Property Office, the disclosure of which is incorporated herein in its entirety by reference.

### BACKGROUND

1. Field of the Invention

The present invention relates to a semiconductor memory device that uses a metal nitride as a trap site, and more particularly, to a semiconductor memory device having improved thermal stability and electrical characteristics by including a metal nitride as a trap site in a charge storage layer and a method of manufacturing the same.

2. Description of the Related Art

The development of semiconductor memory devices has focused on increasing the storage capacity, as well as the programming and erasing speeds. A typical semiconductor memory array structure includes a plurality of memory unit cells connected by circuitry. The information storage capacity of the memory device is proportional to the integration density of the semiconductor memory device. A unit cell of a non-volatile semiconductor memory device, such as a dynamic random access memory (DRAM), includes one transistor and one capacitor.

Recently, new types of semiconductor memory devices having new operation principles have been introduced. For example, semiconductor memory devices having a giant magneto-resistance (GMR) structure and a tunneling magneto-resistance (TMR) structure formed on a transistor have been introduced. Also, new structures of non-volatile semiconductor memory devices, such as a phase change random access memory (PRAM) that uses a phase change material and a silicon-oxide-nitride-oxide-silicon (SONOS) device having a tunneling oxide layer, a change storing layer, and a blocking oxide layer, have been introduced.

FIG. 1 is a cross-sectional view of a conventional SONOS memory device. Referring to FIG. 1, first and second doped regions 12a and 12b doped with a dopant are included in a semiconductor substrate 11. A channel region 13 is defined in the semiconductor substrate 11 between the first and second doped regions 12a and 12b. A gate structure 14 is formed on the channel region 13. The gate structure 14 includes a tunneling oxide layer 15, a charge storing layer 16, a blocking oxide layer 17, and a gate electrode layer 18 formed of a conductive material, which are sequentially formed.

The tunneling oxide layer 15 contacts the source region 12a and the drain region 12b thereunder, and the charge storing layer 16 includes a trap site for trapping a charge passing through the tunneling oxide layer 15. Information is recorded in the SONOS memory device when electrons are trapped in the trap site of the charge storing layer 16 after passing through the tunneling oxide layer 15 under a voltage applied to the memory device.

In the SONOS memory device, a threshold voltage Vₜₕ varies depending on whether electrons are trapped in the charge storing layer 16. The blocking oxide layer 17 blocks electrons from leaking into the gate electrode layer 18 while the electrons are trapped in the trap site of the charge storing layer 16 and further blocks a charge of the gate electrode layer 18 from being injected into the charge storing layer 16.

The SONOS memory device needs a thin tunneling oxide layer to increase the programming and erasing speed. However, this reduces the information retention characteristics. Also, to prevent the blocking oxide layer 17 from tunneling electrons from the gate electrode layer 18 to infiltrate the charge storing layer 16, a thick blocking oxide layer 17 must be formed. However, if the blocking oxide layer 17 is overly thick, control of the channel region 13 of the gate electrode layer 18 would be difficult. To prevent this problem, a non-volatile memory device that uses a silicon nano crystal (Si—NC) in the charge storing layer 16 has been introduced. However, this structure has low charge storage efficiency and short information retention time since the non-volatile memory device that uses the Si—NC in the charge storing layer 16 has a similar band gap energy to the semiconductor substrate 11. Also, the non-volatile memory device using the Si—NC in the charge storing layer 16 has a reduced trap site compared to the SONOS memory device.

As a method of solving the problems of the non-volatile memory device described above, a structure that includes a metal nano crystal trap site has been introduced. This structure can improve the information retention characteristics with respect to the information programming, as well as being able to improve the erasing speed by controlling a work function. However, in this structure, interface characteristics of the memory device are degraded due to the phenomenon of metal diffusion during annealing, which is a requisite process during the manufacturing of the memory devices, and eventually reduces the electrical characteristics of the memory device.

### SUMMARY

In one embodiment, a memory device includes a gate structure comprising a metal nitride material in a charge storing layer on a semiconductor substrate. The gate structure is disposed between a first dopant region and a second dopant region formed on the semiconductor substrate. The metal nitride material is structured to function as a trap site for trapping a charge.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a conventional memory device;

FIG. 2 is a cross-sectional view of a memory device that uses a metal nitride as a trap site according to one embodiment of the present invention;

FIGS. 3A through 3E are cross-sectional views illustrating a method of manufacturing a memory device that uses a metal nitride as a trap site according to another embodiment of the present invention;

FIGS. 4A through 4C are images of trap sites, the sizes of which are controlled by controlling sputtering conditions while manufacturing a memory device that uses a metal nitride as the trap site according to yet another embodiment of the present invention;

FIGS. 5A through 5C are graphs showing electrical characteristics of a memory device that uses a metal nitride as a trap site according to an embodiment of the present invention;

FIG. 6 is a graph showing XRD measurement results of a memory device that uses a metal nitride as a trap site according to still another embodiment of the present invention; and

FIGS. 7A and 7B are graphs showing XPS measurement results of a memory device that uses a metal nitride as a trap site according to another embodiment of the present invention.

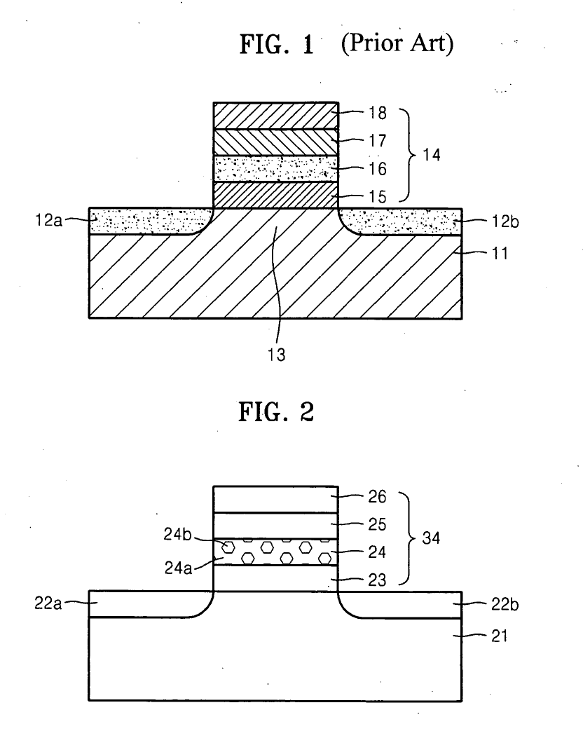

### DETAILED DESCRIPTION

The present invention will now be described more fully with reference to the accompanying drawings in which exemplary embodiments of the invention are shown. In the drawings, the thicknesses of layers and regions are exaggerated for clarity.

FIG. 2 is a cross-sectional view illustrating a semiconductor device such as a memory device that uses a metal nitride as a trap site according to an embodiment of the present invention.

Referring to FIG. 2, first and second dopant regions 22a and 22b doped with a dopant are formed on a substrate 21. A gate structure 34 is formed on the substrate 21 between the first and second dopant regions 22a and 22b. In the gate structure 34, a tunneling dielectric layer such as a tunneling oxide layer 23, a charge storing layer 24 that includes a trap site, a blocking dielectric layer such as a blocking oxide layer 25, and a gate electrode layer 26 are sequentially formed.

Here, the tunneling oxide layer 23 and the blocking oxide layer 25 are formed of an insulating material, such as SiO₂, and the gate electrode layer 26 is formed of a conductive material.

According to an aspect of the present invention, the charge storing layer 24 includes a metal nitride as a trap site. In particular, the charge storing layer 24 includes a metal nitride 24b as the trap site in a dielectric layer 24a formed of a high-k material having a dielectric constant greater than that of SiO₂. For example, the dielectric layer 24a is formed of a high-k material such as Al₂O₃, ZrO₂, HfO₂ or Si₃N₄.

More particularly, nano-sized particles comprising metal nitride are dispersed in the charge storing layer 24 as the trap site. The nano-sized particles may have a substantially uniform size, for example, having a diameter of about 1 nm to about 10 nm, and may be regularly arrayed in the dielectric layer 24a such as a silicon dioxide layer.

The terms “nano-sized” as used in the following description and claims are meant to refer to particles having linear dimensions in the range from about 1 nm to about 100 nm.

According to another aspect of the present invention, the metal nitride 24b may include a metal, especially a transition metal such as titanium, cobalt or nickel? or a lanthanide group metal (La, Ce, Pr, Nd, Pm, Sm, Eu, Gd, Yb, Tb, Dy, Rb, Er, Tm, Lu), and may further include silicon, aluminum, or boron. The chemical formula of the metal compound may be MN, MSiN, MAIN, or MBN. Here, M may mean the transition metal or the lengthanide group metal.

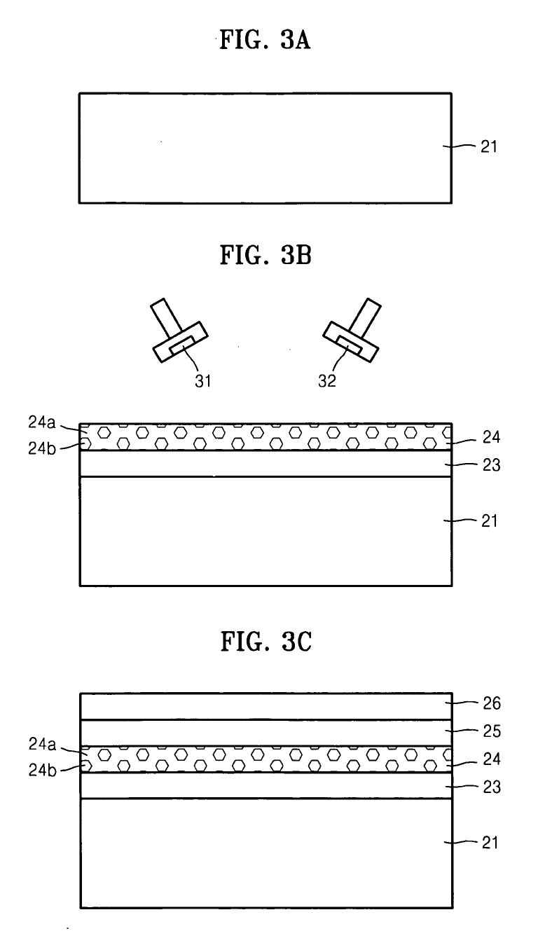

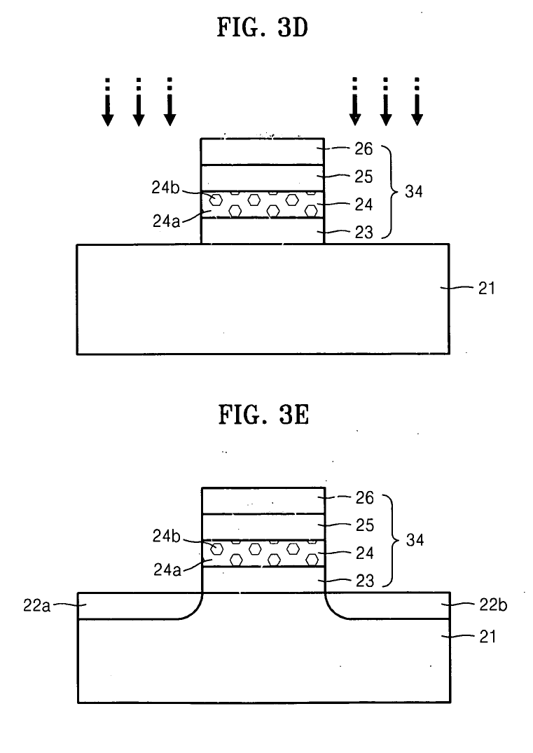

A method of manufacturing the memory device that uses a metal nitride as a trap site as depicted in FIG. 2 will now be described with reference to FIGS. 3A through 3E.

Referring to FIG. 3A, a semiconductor substrate 21 is prepared. The semiconductor substrate 21 can be formed of any material used for manufacturing a semiconductor memory device, and may include Si.

Referring to FIG. 3B, a tunneling dielectric layer such as a tunneling oxide layer 23 is deposited on the semiconductor substrate 21. The tunneling oxide layer 23 can be formed by depositing an insulating material, such as SiO₂ or SiN, using a conventional semiconductor manufacturing process.

After the tunneling oxide layer 23 is formed, a charge storing layer 24 that includes a metal nitride is formed on the tunneling oxide layer 23. To form the charge storing layer 24, a co-sputtering process may be used. More specifically, the charge storing layer 24 is formed on the tunneling oxide layer 23, using a first target 31 that includes a dielectric material and a second target 32 that includes a metal nitride, in a process chamber filled with a gas, such as argon (Ar). The dielectric layer 24a can be formed using a high-k material, such as Al₂O₃, HfO₂, ZrO₂ or Si₃N₄. The metal nitride 24b may include a metal, especially a transition metal or a lanthanide group metal, and may further include silicon, aluminum, or boron. The chemical formula of the metal compound may be MN, MSiN, MAlN, or MBN. An aspect of this embodiment is that in the sputtering process, the size of the metal nitride 24b formed in the dielectric layer 24a can be controlled by controlling the RF power applied to the first and second targets 31 and 32.

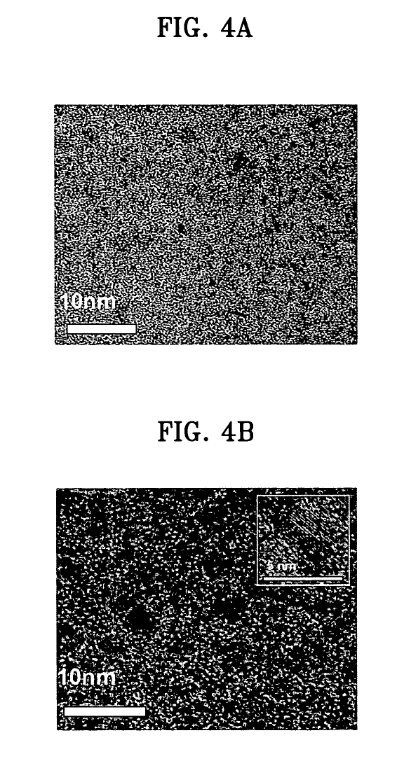

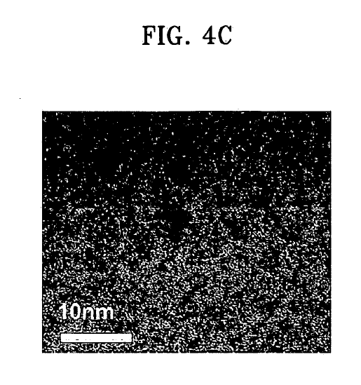

FIGS. 4A through 4C are images of the surfaces of specimens according to the magnitude of sputtering RF power applied to the first target 31 that includes a dielectric material and the second target 32 that includes a metal nitride, during a sputtering process for forming the charge storing layer 24 of a memory device according to an embodiment of the present invention. In these examples, the first target 31 is Al₂O₃ and the second target 32 is TiN.

FIG. 4A is an image of a charge storing layer when an RF power of approximately 50 W is applied to the first target 31 and an RF power of about 10 W is applied to the second target 32. FIG. 4B is an image of a charge storing layer when an RF power of approximately 50 W is applied to the first target 31 and an RF power of about 30 W is applied to the second target 32. FIG. 4C is an image of a charge storing layer when an RF power of approximately 50 W is applied to the first target 31 and an RF power of about 60 W is applied to the second target 32. That is, the metal nitride is formed by applying a fixed RF power of approximately 50 W to the first target 31 formed of Al₂O₃ and applying a gradually increasing RF power of about 10 W, 30 W and 60 W to the second target 32 formed of TiN.

Referring to FIGS. 4A through 4C, darker areas are trap sites formed of a metal nitride, and the size of the trap sites gradually increases as the RF power applied to the second target 32 formed of the metal nitride increases. From this result, in the method of manufacturing a memory device that includes the metal nitride as the trap sites according to an embodiment of the present invention, the size of the trap sites can be controlled in co-sputtering by controlling the RF power applied to the first target 31 that includes a dielectric layer and the second target 32 that includes the metal nitride.

Referring to FIG. 3C, after the charge storing layer 24 is formed, a blocking dielectric layer such as a blocking oxide layer 25 and a gate electrode layer 26 are formed on the charge storing layer 24. The blocking oxide layer 25 can be formed of any insulating material used for forming conventional memory devices. The gate electrode layer 26 is formed by depositing a conductive material on the blocking oxide layer 25.

Referring to FIG. 3D, a gate structure 34 is formed by patterning etching the tunneling oxide layer 23, the charge storing layer 24, the blocking oxide layer 25, and the gate electrode layer 26. As a result, the upper surfaces of the semiconductor substrate 21 on both sides of the gate structure 34 are exposed. Portions of the exposed upper surface of the semiconductor substrate 21 are then doped with dopants or impurities.

Referring to FIG. 3E, a first doped region 22a and a second doped region 22b are formed by doping the exposed upper surfaces of the semiconductor substrate 21 as described above. By annealing the resultant structure, the manufacture of a memory device that includes a metal nitride as a trap site according to an embodiment of the present invention is completed.

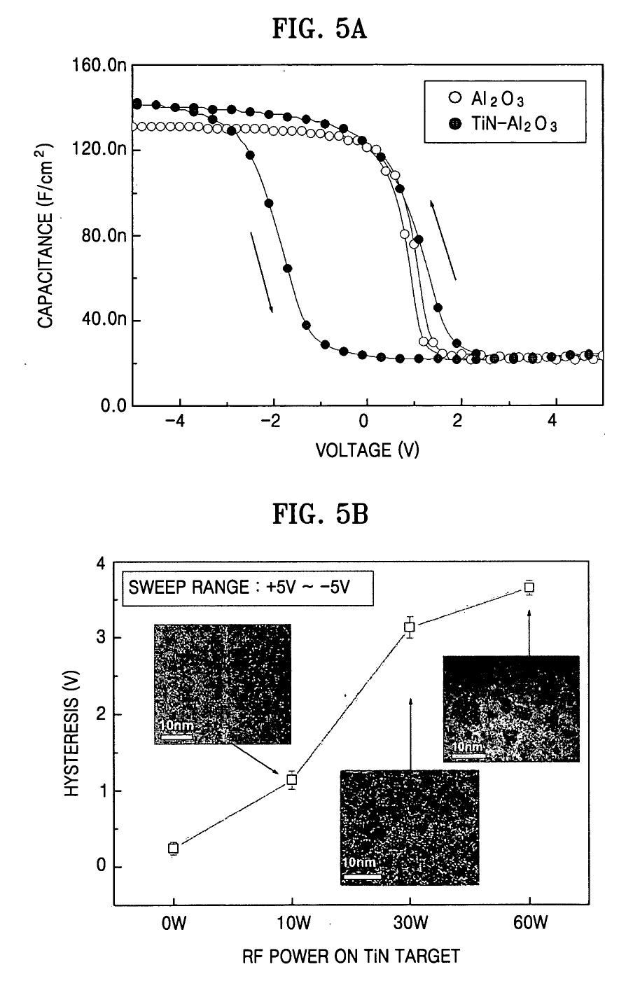

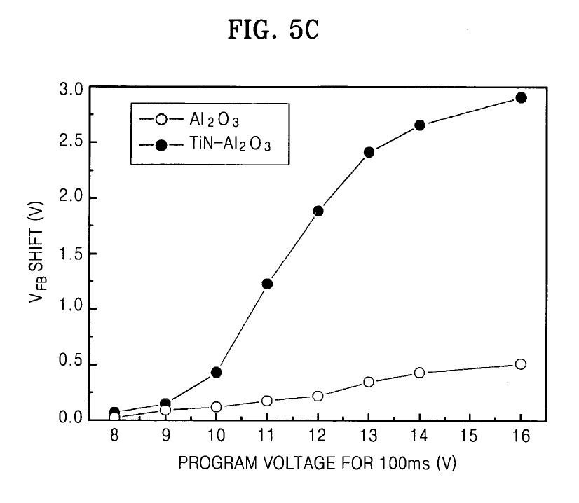

FIGS. 5A through 5C are graphs showing electrical characteristics of a memory device that uses metal nitride as a trap site according to an embodiment of the present invention.

FIG. 5A is a graph of the dielectric constant with respect to voltage V applied to a specimen for which an RF power of about 50 W is applied to the first target 31 formed of Al₂O₃ and an RF power of about 30 W is applied to the second target 32 formed of TiN. FIG. 5A also shows the dielectric constant with respect to voltage applied to a specimen formed of only Al₂O₃. Referring to FIG. 5A, the specimen including TiN as the trap site has a much wider C-V hysteresis width than the specimen formed of only Al₂O₃.

FIG. 5B is a graph showing C-V hysteresis of the specimens for which an RF power of about 50 W is applied to the first target 31 formed of Al₂O₃ and an RF power of about 10 to about 60 W is applied to the second target 32 formed of TiN. Referring to FIG. 5B, as the RF power applied to the second target 32 increases, the C-V hysteresis width gradually increases.

FIG. 5C is a graph showing V_{FB} (flat band voltage) with respect to the programming voltage Vp of a conventional memory device that uses Al₂O₃ in a charge storing layer and a memory device according to an embodiment of the present invention. Referring to FIG. 5C, the memory device that uses a metal nitride as a trap site according to an embodiment of the present invention has a much higher V_{FB} than the conventional memory device that uses Al₂O₃ as the charge storing layer. This result denotes that the memory device that uses a metal nitride as a trap site according to an embodiment of the present invention may have superior charge storing characteristics as compared to conventional devices.

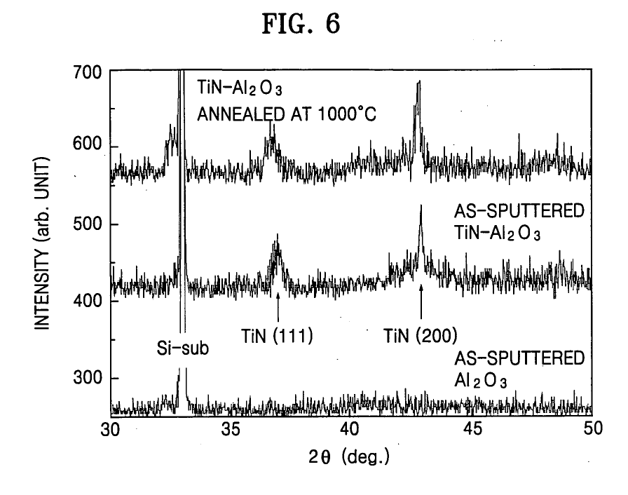

FIG. 6 is a graph showing X-ray diffraction (XRD) measurement results of a memory device that uses a metal nitride as a trap site according to an embodiment of the present invention. The XRD shows the thermal stability of the memory device. Referring to FIG. 6, in the case of a specimen on which TiN—Al₂O₃ is deposited (as-sputtered state), TiN peaks (111) and (200) are detected. These peaks (111) and (200) are still detected after the specimen is annealed at a temperature of about 1000° C. for about 30 seconds.

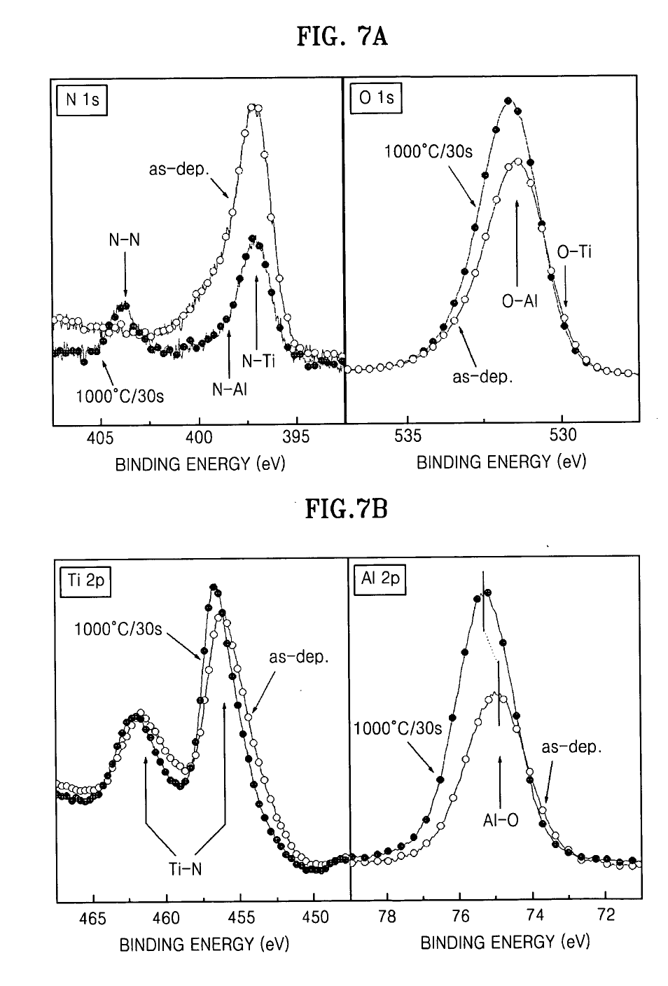

FIGS. 7A and 7B are graphs showing X-Ray Photoelectron Spectroscopy (XPS) measurement results of the characteristics of N 1s, O 1s, Ti 2p, and Al 2p after a TiN—Al₂O₃ specimen is annealed at a temperature of about 1000° C. for about 30 seconds as in FIG. 6. Referring to FIG. 7A, peaks for the characteristics of N atoms are observed after the specimen is annealed at about 1000° C. for about 30 seconds. Referring to FIG. 7B, peaks for the characteristics related to the combining of Ti—N are observed.

The results described with reference to FIGS. 6, 7A, and 7B illustrate the high thermal stability and excellent electrical characteristics of the memory device embodiments of the present invention that use a metal nitride as a trap site.

While some embodiments of the present invention have been particularly shown and described with reference to embodiments thereof, they should not be construed as being limited to the embodiments set forth herein. That is, the aspect of the present invention can be applied to SONOS memory devices, floating gate type flash memory devices, and various memory devices that include a trap site.

According some embodiments of to the present invention, a memory device having high thermal stability and improved information storing, erasing, and retention characteristics can be provided by using a metal nitride as a trap site in a charge storing layer of a non-volatile memory device. Such a device appears to have much more desirable electrical characteristics as compared to conventional memory devices that include a metal nano crystal.

Also, some embodiments of the present invention provide methods of manufacturing a memory device in which the metal nitride can be readily formed in the trap site using a co-sputtering process.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Having described and illustrated the principles of the invention in several preferred embodiments, it should be apparent that the embodiments may be modified in arrangement and detail without departing from such principles. We claim all modifications and variation coming within the spirit and scope of the following claims.

What is claimed is:

1. A memory device comprising:
a semiconductor substrate;
a first dopant region and a second dopant region formed on the semiconductor substrate; and
a gate structure formed on the semiconductor substrate, the gate structure disposed between the first and second dopant region, the gate structure comprising metal nitride in a charge storing layer, the metal nitride configured to store a charge as a trap site.

2. The memory device of claim 1, wherein the gate structure comprises a tunneling dielectric layer, the charge storing layer, a blocking dielectric layer, and a gate electrode layer, which are formed sequentially.

3. The memory device of claim 1, wherein the metal nitride comprises a material having a chemical formula of MN, MSiN, MAIN, or MBN, where M is one of a transition metal and a lanthanide group metal.

4. The memory device of claim 3, wherein the lanthanide group metal is chosen from La, Ce, Pr, Nd, Pm, Sm, Eu, Gd, Yb, Tb, Dy, Rb, Er, Tm, and Lu

5. The memory device of claim 3, wherein the transition metal comprises titanium, cobalt or nickel?.

6. The memory device of claim 3, wherein the charge storing layer is formed of a dielectric material and the metal nitride is formed in the dielectric material as the trap site.

7. The memory device of claim 6, wherein the dielectric material comprises SiO₂ or a material having a dielectric constant greater than that of SiO₂.

8. A semiconductor device comprising:
a semiconductor substrate;
a first dopant region and a second dopant region formed on the semiconductor substrate; and
a gate structure formed on the semiconductor substrate, the gate structure disposed between the first and second dopant region,
wherein the gate structure comprises a plurality of metal nitride particles spaced apart from each other in a dielectric layer, the metal nitride particles configured to store charges as a trap site.

9. The device of claim 8, wherein the dielectric layer comprises SiO₂ or a material having a dielectric constant greater than that of SiO₂.

10. The device of claim 8, wherein the metal nitride particles are nano-sized particles.

11. The device of claim 10, wherein the nano-sized particles having a diameter of about 1 nm to about 10 nm.

12. A method of manufacturing a memory device, comprising:
sequentially forming a tunneling dielectric layer, a charge storing layer that comprises a metal nitride as a trap site, a blocking dielectric layer, and a gate electrode layer on a semiconductor substrate;
patterning the tunneling dielectric layer, the charge storing layer, the blocking dielectric layer, and the gate electrode layer to expose surfaces of the semiconductor substrate; and
forming a first doped region and a second doped region by doping a dopant on a portion of the exposed surfaces of the semiconductor substrate.

13. The method of claim 12, wherein the charge storing layer is formed by a co-sputtering process.

14. The method of claim 13, wherein the charge storing layer is formed by simultaneously sputtering a first target formed of a material including a dielectric material and a second target formed a material including a metal nitride.

15. The method of claim 14, wherein the dielectric material is formed of a material having a dielectric constant greater than that of SiO₂, and the metal nitride is a material having a chemical formula of MN, MSiN, MAlN, or MBN, where M is one of a transition metal and a lanthanide group metal.

16. A semiconductor device formed by processing steps comprising:
sequentially forming a tunneling dielectric layer, a charge storing layer that comprises a metal nitride as a trap site, a blocking dielectric layer, and a gate electrode layer on a semiconductor substrate;
patterning the tunneling dielectric layer, the charge storing layer, the blocking dielectric layer, and the gate electrode layer to expose surfaces of the semiconductor substrate; and
forming a first doped region and a second doped region by doping a dopant on a portion of the exposed surfaces of the semiconductor substrate.

17. The method of claim 16, wherein the charge storing layer is formed by a co-sputtering process.

18. The method of claim 17, wherein the charge storing layer is formed by simultaneously sputtering a first target formed of a material including a dielectric material and a second target formed a material including a metal nitride.

19. The method of claim 18, wherein the dielectric material is formed of a material having a dielectric constant greater than that of SiO₂, and the metal nitride comprises a material having a chemical formula of MN, MSiN, MAlN, or MBN, where M is one of a transition metal and a lanthanide group metal.
